(19) United States
(12) Patent Application Publication
(10) Pub. No.: US 2020/0333869 A1
(43) Pub. Date: Oct. 22, 2020

(54) BATTERY MONITORING SYSTEM USING NETWORK CONNECTIVITY

(71) Applicant: INTEL CORPORATION, Santa Clara, CA (US)

(72) Inventor: Ali Syari'ati MOHD SALLEH, Georgetown (MY)

(73) Assignee: INTEL CORPORATION, Santa Clara, CA (US)

(21) Appl. No.: 16/088,011

(22) PCT Filed: Jun. 13, 2017
(86) PCT No.: PCT/US2017/037200

§ 371 Date: Sep. 24, 2018

(30) Foreign Application Priority Data
Jul. 18, 2016 (MY) PI2016702595

(51) Int. Cl. G06F 1/3212; G01R 31/371

(52) U.S. Cl. CPC G06F 1/3212; G01R 31/371

(57) ABSTRACT

In one example a power monitoring module comprises logic, at least partially including hardware logic, to monitor a power supply and generate an alert in response to an alert condition for the power supply, and forward the alert to a communication module to transmit the alert to a remote device. Other examples may be described.

### RELATED APPLICATIONS

This application claims priority under 35 U.S.C. § 365(c) to MY Application No. PI2016702595 filed on Jul. 18, 2016, entitled BATTERY MONITORING SYSTEM USING NETWORK CONNECTIVITY. The entire disclosure of these documents are incorporated by reference herein for all purposes.

### BACKGROUND

The subject matter described herein relates generally to the field of remote monitoring and more particularly to a battery monitoring system which uses network connectivity.

Many electronic systems operate on battery power as either a primary power source or as a backup power source in the event that the primary power source fails. Some electronic systems may reside in remote locations. Accordingly, battery monitoring systems which utilize network connectivity may find utility.

### BRIEF DESCRIPTION OF THE DRAWINGS

The detailed description is described with reference to the accompanying figures.

FIG. 1 is a schematic illustration of an architecture to implement battery monitoring using network connectivity in accordance with some examples.

FIG. 2 is a schematic illustration of an electronic device which may be adapted to implement battery monitoring using network connectivity in accordance with some examples.

FIGS. 3A-3C, 4 and 5 are flowcharts illustrating operations in a method to implement battery monitoring using network connectivity in accordance with some examples.

FIGS. 6-10 are schematic illustrations of electronic devices which may be adapted to implement battery monitoring using network connectivity in accordance with some examples.

### DETAILED DESCRIPTION

Described herein are exemplary systems and methods to implement battery monitoring using network connectivity. In the following description, numerous specific details are set forth to provide a thorough understanding of various examples. However, it will be understood by those skilled in the art that the various examples may be practiced without the specific details. In other instances, well-known methods, procedures, components, and circuits have not been illustrated or described in detail so as not to obscure the particular examples.

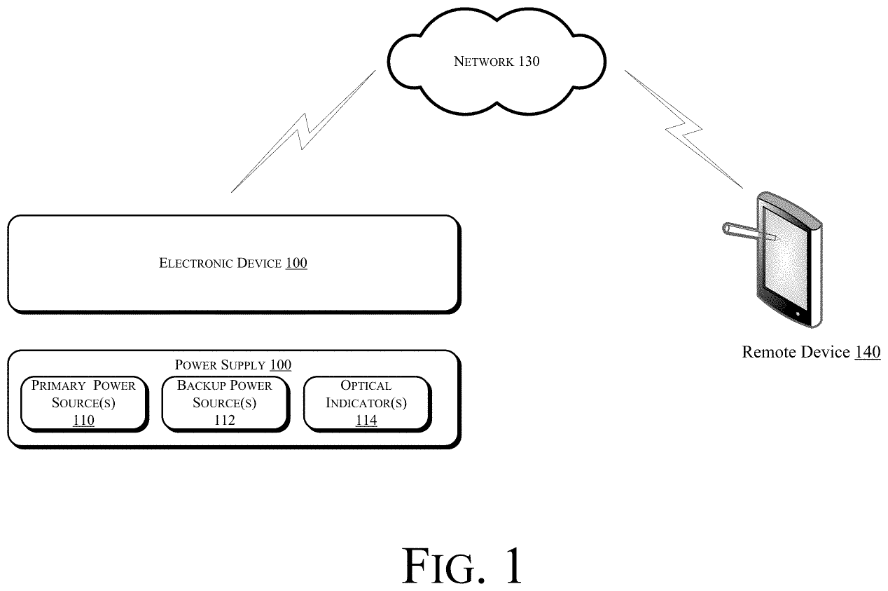

FIG. 1 is a schematic illustration of an architecture to implement battery monitoring using network connectivity in accordance with some examples. Referring to FIG. 1, in some examples a power supply 100 may comprise one or more primary power sources 110, one or more backup power sources 112, and one or more optical indictors 114 which generate an optical output that is a function of a power state of the power supply 100. For example, the primary power source(s) 110 may comprise an alternating current (AC) power source, while the backup power source(s) 112 may comprise a direct current (DC) power storage unit, e.g., a battery or the like. The optical indicator(s) may comprise one or more light emitting diodes (LEDs).

In some examples an electronic device such as electronic device 100 may monitor the status of the power supply 100. Electronic device 100 may be coupled to a network 130 by a communication connection. One or more remote devices 140 may be communicatively coupled to the electronic device 100 via communication network 130.

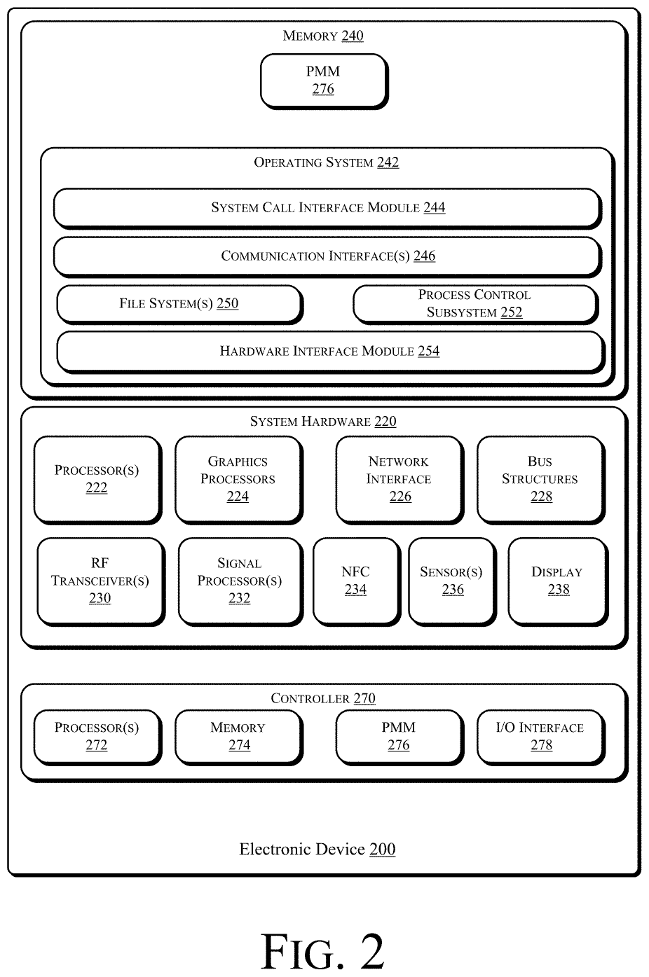

FIG. 2 is a schematic illustration of an electronic device 100 which may be adapted to implement battery monitoring using network connectivity in accordance with some examples. Referring to FIG. 2, in various examples, electronic device 200 may include or be coupled to one or more accompanying input/output devices including a display, one or more speakers, a keyboard, one or more other I/O device(s), a mouse, a camera, or the like. Other exemplary I/O device(s) may include a touch screen, a voice-activated input device, a track ball, a geolocation device, an accelerometer/gyroscope, biometric feature input devices, and any other device that allows the electronic device 200 to receive input from a user.

The electronic device 200 includes system hardware 220 and memory 240, which may be implemented as random access memory and/or read-only memory. A file store may be communicatively coupled to electronic device 200. The file store may be internal to electronic device 200 such as, e.g., eMMC, SSD, one or more hard drives, or other types of storage devices. Alternatively, the file store may also be external to electronic device 200 such as, e.g., one or more external hard drives, network attached storage, or a separate storage network.

System hardware 220 may include one or more processors 222, graphics processors 224, network interfaces 226, and bus structures 228. In one embodiment, processor 222 may be embodied as an Intel® Atom™ processors, Intel® Atom™ based System-on-a-Chip (SOC) or Intel® Core2 Duo® or i3/i5/i7 series processor available from Intel Corporation, Santa Clara, Calif., USA. As used herein, the term “processor” means any type of computational element, such as but not limited to, a microprocessor, a microcontroller, a complex instruction set computing (CISC) microprocessor, a reduced instruction set (RISC) microprocessor, a very long instruction word (VLIW) microprocessor, or any other type of processor or processing circuit.

Graphics processor(s) 224 may function as adjunct processor that manages graphics and/or video operations. Graphics processor(s) 224 may be integrated onto the motherboard of electronic device 200 or may be coupled via an expansion slot on the motherboard or may be located on the same die or same package as the Processing Unit.

In one embodiment, network interface 226 could be a wired interface such as an Ethernet interface (see, e.g., Institute of Electrical and Electronics Engineers/IEEE 802.3-2002) or a wireless interface such as an IEEE 802.11a, b or g-compliant interface (see, e.g., IEEE Standard for IT-Telecommunications and information exchange between systems LAN/MAN—Part II: Wireless LAN Medium Access Control (MAC) and Physical Layer (PHY) specifications Amendment 4: Further Higher Data Rate Extension in the 2.4 GHz Band, 802.11G-2003). Another example of a wireless interface would be a general packet radio service (GPRS) interface (see, e.g., Guidelines on GPRS Handset Requirements, Global System for Mobile Communications/GSM Association, Ver. 3.0.1, December 2002).

Bus structures 228 connect various components of system hardware 228. In one embodiment, bus structures 228 may be one or more of several types of bus structure(s) including a memory bus, a peripheral bus or external bus, and/or a local bus using any variety of available bus architectures including, but not limited to, 11-bit bus, Industrial Standard Architecture (ISA), Micro-Channel Architecture (MSA), Extended ISA (EISA), Intelligent Drive Electronics (IDE), VESA Local Bus (VLB), Peripheral Component Interconnect (PCI), Universal Serial Bus (USB), Advanced Graphics Port (AGP), Personal Computer Memory Card International Association bus (PCMCIA), and Small Computer Systems Interface (SCSI), a High Speed Synchronous Serial Interface (HSI), a Serial Low-power Inter-chip Media Bus (SLIMbus®), or the like.

Electronic device 200 may include an RF transceiver 230 to transceiver RF signals, a Near Field Communication (NFC) radio 234, and a signal processing module 232 to process signals received by RF transceiver 230. RF transceiver may implement a local wireless connection via a protocol such as, e.g., Bluetooth or 802.11X. IEEE 802.11a, b or g-compliant interface (see, e.g., IEEE Standard for IT-Telecommunications and information exchange between systems LAN/MAN—Part II: Wireless LAN Medium Access Control (MAC) and Physical Layer (PHY) specifications Amendment 4: Further Higher Data Rate Extension in the 2.4 GHz Band, 802.11G-2003). Another example of a wireless interface would be a WCDMA, LTE, general packet radio service (GPRS) interface (see, e.g., Guidelines on GPRS Handset Requirements, Global System for Mobile Communications/GSM Association, Ver. 3.0.1, December 2002).

Electronic device 200 may further include one or more sensors 236 such as a thermal sensor, a coupling sensor, or the like. Electronic device 200 may further include one or more sensors 236 and a display 238. In some examples the sensors 236 may comprise one or more optical sensors. Further, electronic device 200 may not have a keypad and use the touch panel for input.

Memory 240 may include an operating system 242 for managing operations of electronic device 200. In one embodiment, operating system 242 includes a hardware interface module 254 that provides an interface to system hardware 220. In addition, operating system 240 may include a file system 250 that manages files used in the operation of electronic device 200 and a process control subsystem 252 that manages processes executing on electronic device 200.

Operating system 242 may include (or manage) one or more communication interfaces 246 that may operate in conjunction with system hardware 220 to transceive data packets and/or data streams from a remote source. Operating system 242 may further include a system call interface module 244 that provides an interface between the operating system 242 and one or more application modules resident in memory 230. Operating system 242 may be embodied as a UNIX operating system or any derivative thereof (e.g., Linux, Android, etc.) or as a Windows® brand operating system, or other operating systems.

In some examples an electronic device may include a controller 270, which may comprise one or more controllers that are separate from the primary execution environment. The separation may be physical in the sense that the controller may be implemented in controllers which are physically separate from the main processors. Alternatively, the trusted execution environment may be logical in the sense that the controller may be hosted on same chip or chipset that hosts the main processors.

By way of example, in some examples the controller 270 may be implemented as an independent integrated circuit located on the motherboard of the electronic device 200, e.g., as a dedicated processor block on the same SOC die. In other examples the trusted execution engine may be implemented on a portion of the processor(s) 222 that is segregated from the rest of the processor(s) using hardware enforced mechanisms.

In the embodiment depicted in FIG. 2 the controller 270 comprises a processor 272, a memory module 274, a power monitoring module (PMM) 276, and an I/O interface 278. In some examples the memory module 274 may comprise a persistent flash memory module and the various functional modules may be implemented as logic instructions encoded in the persistent memory module, e.g., firmware or software. The I/O module 278 may comprise a serial I/O module or a parallel I/O module. Because the controller 270 is separate from the main processor(s) 222 and operating system 242, the controller 270 may be made secure, i.e., inaccessible to hackers who typically mount software attacks from the host processor 222. In some examples portions of the power monitoring module 276 may reside in the memory 240 of electronic device 200 and may be executable on one or more of the processors 522.

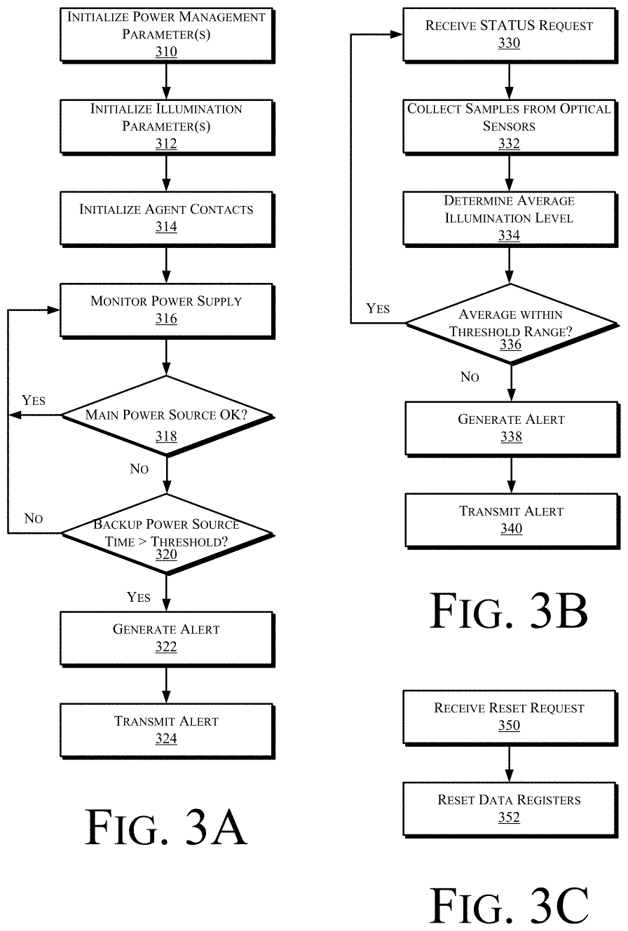

Having described various structures of a system to implement a battery monitoring system using network connectivity, operating aspects of a system will be explained with reference to FIGS. 3A-3C, 4 and 5. In some examples the operations depicted in the flowcharts may be implemented by the power monitoring module 276, alone or in combination with other component of electronic device 100.

Referring to FIG. 3A, in some examples the power monitoring module 276 initializes one or more power management parameters for the monitoring system. Examples of parameters to be initialized may comprise a high voltage battery indicator, a low voltage battery indicator, a designation of a charger fail in the power supply, a designation of a main power (e.g., an AC) supply fail, a designation of a DC supply fail. Further, one or more charge threshold parameters may be designated. In some examples an upper charge threshold and a lower charge threshold may be designated at initialization. The thresholds may be set at predetermined values which may be fixed values (e.g., a fixed charge percentage) or may be variable depending upon one or more operating parameters, e.g., power draw from the backup power source(s).

At operation 314 the power monitoring module 276 may initialize one or more agent contacts. By way of example, contact information for one or more remote devices 140 may be entered into the electronic device 100 during the initialization process.

At operation 316, the power monitoring module 276 may be activated to monitor the power supply 200. If, at operation 318, the main power supply is operating correctly then control passes back to operation 316 and the power monitoring module 276 continues to monitor the power supply. By contrast, if at operation 318 the main power supply is not operating correctly and the backup power supply has been activated, then control passes to operation 320.

If, at operation 320, the backup power source has not been operational for more than a predetermined time threshold then control passes back to operation 316 and the power monitoring module 276 continues to monitor the power supply. In some examples the predetermined time threshold may be static (e.g., a fixed number of minutes or hours). In other examples the predetermined time threshold may be dynamic and may determined as a function of one or more operating parameters, e.g., power draw from the backup power source(s)

By contrast, if at operation 320 the backup power supply has been operational for more than a predetermined time threshold then control passes to operation 322 and the power monitoring module 276 generates an alert, which is transmitted to one or more remote devices 140 via the communication network 130. In some examples the alert may comprise an indicator of the charge status of the backup power source(s) 112.

In some examples the power monitoring module 276 may comprise logic which, when executed, configures the power monitoring module to respond to requests from a remote device 140. Referring to FIG. 3B, in some examples the power monitoring module 276 may receive a Status request from a remote device 140. By way of example the Status request may be transmitted to the electronic device 100 via communication network 130, e.g., in a text message or the like.

In response to the Status request, at operation 332 the power monitoring module 276 collects samples from the optical sensor(s) 136. In some examples the optical sensors 136 may be positioned to detect the output from the optical indicators 114 on power supply 200. The power monitoring module 276 may collect a number, N, of samples from the optical indicators over a predetermined time period. For example, the number N may be in a range between 10 and 100 samples which may be collected in a time period lasting between 5 seconds and 2 minutes.

At operation 334 the power monitoring module 276 determines an average illumination level of the optical indicators 114. By way of example the power monitoring module 276 may determine an average lux value of the illumination generated by the optical indicators 114.

If, at operation 336, the average illumination level is within a threshold ranged then control passes back to operation 330 and the power monitoring module 276 may wait for another Status request. In some examples the threshold range may be set during the initialization process of operation 312.

By contrast, if at operation 336 the average illumination level of the optical indicators is outside the threshold range then control passes to operation 338 and the power monitoring module 276 generates an alert, which is transmitted to one or more remote devices 140 via the communication network 130. In some examples the alert may comprise an indicator of the charge status of the backup power source(s) 112.

Referring to FIG. 3C, in some examples the power monitoring module 276 may receive, at operation 350, a Reset request from a remote device 140. By way of example the Status request may be transmitted to the electronic device 100 via communication network 130, e.g., in a text message or the like.

In response to the Reset request, at operation 352 the power monitoring module 276 resets data registers in the memory 174 of controller 170.

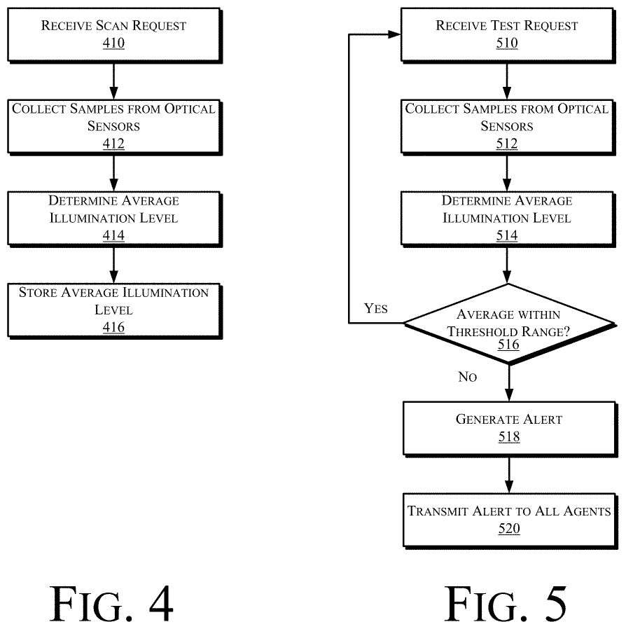

In some examples the power monitoring module 276 may comprise logic which, when executed, configures the power monitoring module to respond to inputs to the power monitoring module 276 via one or more input devices via the I/O interface 178. Referring to FIG. 4, in some examples the power monitoring module 276 may receive a Scan request via the I/O interface 178. In some examples the Scan request may be entered by a predetermined character sequence on an input device such as a keypad or a touch screen.

In response to the Reset request, at operation 412 the power monitoring module 276 collects samples from the optical sensor(s) 136. As described above, in some examples the optical sensors 136 may be positioned to detect the output from the optical indicators 114 on power supply 200. The power monitoring module 276 may collect a number, N, of samples from the optical indicators over a predetermined time period. For example, the number N may be in a range between 100 and 300 samples which may be collected in a time period lasting between 30 seconds and 5 minutes.

At operation 414 the power monitoring module 276 determines an average illumination level of the optical indicators 114. By way of example the power monitoring module 276 may determine an average lux value of the illumination generated by the optical indicators 114. At operation 416 the average illumination level may be stored in a memory such as memory 174.

Referring to FIG. 5, in some examples the power monitoring module 276 may receive a Test request via the I/O interface 178. In some examples the Test request may be entered by a predetermined character sequence on an input device.

In response to the Test request, at operation 512 the power monitoring module 276 collects samples from the optical sensor(s) 136. The power monitoring module 276 may collect a number, N, of samples from the optical indicators over a predetermined time period. For example, the number N may be in a range between 30 and 100 samples which may be collected in a time period lasting between 5 seconds and 2 minutes.

At operation 514 the power monitoring module 276 determines an average illumination level of the optical indicators 114. By way of example the power monitoring module 276 may determine an average lux value of the illumination generated by the optical indicators 114.

If, at operation 516, the average illumination level is within a threshold ranged then control passes back to operation 510 and the power monitoring module 276 may wait for another Test request. In some examples the threshold range may be set during the initialization process of operation 312.

By contrast, if at operation 516 the average illumination level of the optical indicators is outside the threshold range then control passes to operation 518 and the power monitoring module 276 generates an alert, which is transmitted to one or more remote devices 140 via the communication network 130. In some examples the alert may comprise an indicator of the charge status of the backup power source(s) 112.

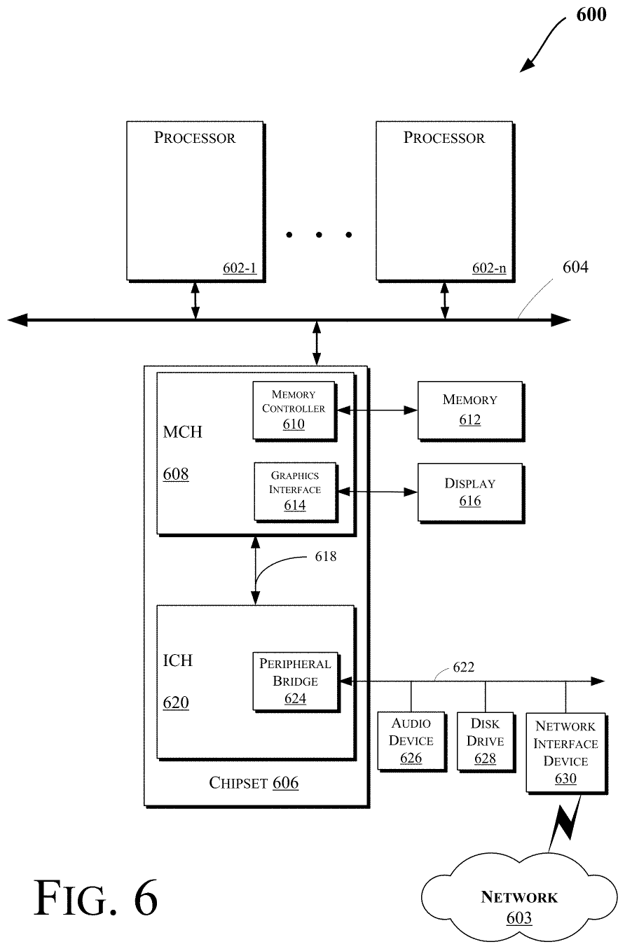

As described above, in some examples the electronic device may be embodied as a computer system. FIG. 6 illustrates a block diagram of a computing system 600 in accordance with an example. The computing system 600 may include one or more central processing unit(s) 602 or processors that communicate via an interconnection network (or bus) 604. The processors 602 may include a general purpose processor, a network processor (that processes data communicated over a computer network 603), or other types of a processor (including a reduced instruction set computer (RISC) processor or a complex instruction set computer (CISC)). Moreover, the processors 602 may have a single or multiple core design. The processors 602 with a multiple core design may integrate different types of processor cores on the same integrated circuit (IC) die. Also, the processors 602 with a multiple core design may be implemented as symmetrical or asymmetrical multiprocessors.

A chipset 606 may also communicate with the interconnection network 604. The chipset 606 may include a memory control hub (MCH) 608. The MCH 608 may include a memory controller 610 that communicates with a memory 612. The memory 612 may store data, including sequences of instructions, that may be executed by the processor 602, or any other device included in the computing system 600. In one example, the memory 612 may include one or more volatile storage (or memory) devices such as random access memory (RAM), dynamic RAM (DRAM), synchronous DRAM (SDRAM), static RAM (SRAM), or other types of storage devices. Nonvolatile memory may also be utilized such as a hard disk. Additional devices may communicate via the interconnection network 604, such as multiple processor(s) and/or multiple system memories.

The MCH 608 may also include a graphics interface 614 that communicates with a display device 616. In one example, the graphics interface 614 may communicate with the display device 616 via an accelerated graphics port (AGP). In an example, the display 616 (such as a flat panel display) may communicate with the graphics interface 614 through, for example, a signal converter that translates a digital representation of an image stored in a storage device such as video memory or system memory into display signals that are interpreted and displayed by the display 616. The display signals produced by the display device may pass through various control devices before being interpreted by and subsequently displayed on the display 616.

A hub interface 618 may allow the MCH 608 and an input/output control hub (ICH) 620 to communicate. The ICH 620 may provide an interface to I/O device(s) that communicate with the computing system 600. The ICH 620 may communicate with a bus 622 through a peripheral bridge (or controller) 624, such as a peripheral component interconnect (PCI) bridge, a universal serial bus (USB) controller, or other types of peripheral bridges or controllers. The bridge 624 may provide a data path between the processor 602 and peripheral devices. Other types of topologies may be utilized. Also, multiple buses may communicate with the ICH 620, e.g., through multiple bridges or controllers. Moreover, other peripherals in communication with the ICH 620 may include, in various examples, integrated drive electronics (IDE) or small computer system interface (SCSI) hard drive(s), USB port(s), a keyboard, a mouse, parallel port(s), serial port(s), floppy disk drive(s), digital output support (e.g., digital video interface (DVI)), or other devices.

The bus 622 may communicate with an audio device 626, one or more disk drive(s) 628, and a network interface device 630 (which is in communication with the computer network 603). Other devices may communicate via the bus 622. Also, various components (such as the network interface device 630) may communicate with the MCH 608 in some examples. In addition, the processor 602 and one or more other components discussed herein may be combined to form a single chip (e.g., to provide a System on Chip (SOC)). Furthermore, the graphics accelerator 616 may be included within the MCH 608 in other examples.

Furthermore, the computing system 600 may include volatile and/or nonvolatile memory (or storage). For example, nonvolatile memory may include one or more of the following: read-only memory (ROM), programmable ROM (PROM), erasable PROM (EPROM), electrically EPROM (EEPROM), a disk drive (e.g., 628), a floppy disk, a compact disk ROM (CD-ROM), a digital versatile disk (DVD), flash memory, a magneto-optical disk, or other types of nonvolatile machine-readable media that are capable of storing electronic data (e.g., including instructions).

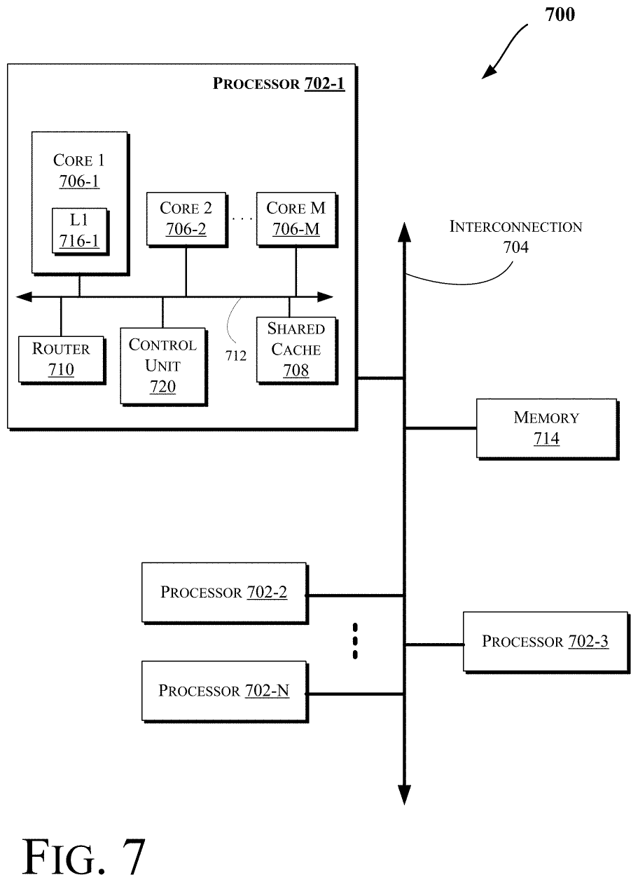

FIG. 7 illustrates a block diagram of a computing system 700, according to an example. The system 700 may include one or more processors 702-1 through 702-N (generally referred to herein as “processors 702” or “processor 702”). The processors 702 may communicate via an interconnection network or bus 704. Each processor may include various components some of which are only discussed with reference to processor 702-1 for clarity. Accordingly, each of the remaining processors 702-2 through 702-N may include the same or similar components discussed with reference to the processor 702-1.

In an example, the processor 702-1 may include one or more processor cores 706-1 through 706-M (referred to herein as “cores 706” or more generally as “core 706”), a shared cache 708, a router 710, and/or a processor control logic or unit 720. The processor cores 706 may be implemented on a single integrated circuit (IC) chip. Moreover, the chip may include one or more shared and/or private caches (such as cache 708), buses or interconnections (such as a bus or interconnection network 712), memory controllers, or other components.

In one example, the router 710 may be used to communicate between various components of the processor 702-1 and/or system 700. Moreover, the processor 702-1 may include more than one router 710. Furthermore, the multitude of routers 710 may be in communication to enable data routing between various components inside or outside of the processor 702-1.

The shared cache 708 may store data (e.g., including instructions) that are utilized by one or more components of the processor 702-1, such as the cores 706. For example, the shared cache 708 may locally cache data stored in a memory 714 for faster access by components of the processor 702. In an example, the cache 708 may include a mid-level cache (such as a level 2 (L2), a level 3 (L3), a level 4 (L4), or other levels of cache), a last level cache (LLC), and/or combinations thereof. Moreover, various components of the processor 702-1 may communicate with the shared cache 708 directly, through a bus (e.g., the bus 712), and/or a memory controller or hub. As shown in FIG. 7, in some examples, one or more of the cores 706 may include a level 1 (L1) cache 716-1 (generally referred to herein as “L1 cache 716”).

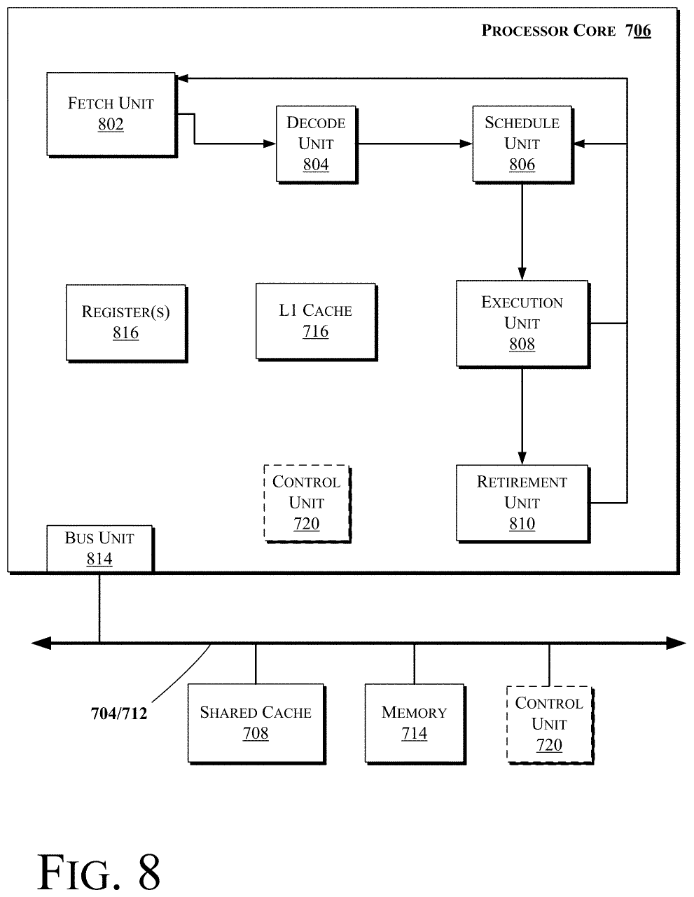

FIG. 8 illustrates a block diagram of portions of a processor core 706 and other components of a computing system, according to an example. In one example, the arrows shown in FIG. 8 illustrate the flow direction of instructions through the core 706. One or more processor cores (such as the processor core 706) may be implemented on a single integrated circuit chip (or die) such as discussed with reference to FIG. 7. Moreover, the chip may include one or more shared and/or private caches (e.g., cache 708 of FIG. 7), interconnections (e.g., interconnections 704 and/or 712 of FIG. 7), control units, memory controllers, or other components.

As illustrated in FIG. 8, the processor core 706 may include a fetch unit 802 to fetch instructions (including instructions with conditional branches) for execution by the core 706. The instructions may be fetched from any storage devices such as the memory 714. The core 706 may also include a decode unit 804 to decode the fetched instruction. For instance, the decode unit 804 may decode the fetched instruction into a plurality of micro-operations.

Additionally, the core 706 may include a schedule unit 806. The schedule unit 806 may perform various operations associated with storing decoded instructions (e.g., received from the decode unit 804) until the instructions are ready for dispatch, e.g., until all source values of a decoded instruction become available. In one example, the schedule unit 806 may schedule and/or issue (or dispatch) decoded instructions to an execution unit 808 for execution. The execution unit 808 may execute the dispatched instructions after they are decoded (e.g., by the decode unit 804) and dispatched (e.g., by the schedule unit 806). In an example, the execution unit 808 may include more than one execution unit. The execution unit 808 may also perform various arithmetic operations such as addition, subtraction, multiplication, and/or division, and may include one or more an arithmetic logic units (ALUs). In an example, a co-processor (not shown) may perform various arithmetic operations in conjunction with the execution unit 808.

Further, the execution unit 808 may execute instructions out-of-order. Hence, the processor core 706 may be an out-of-order processor core in one example. The core 706 may also include a retirement unit 810. The retirement unit 810 may retire executed instructions after they are committed. In an example, retirement of the executed instructions may result in processor state being committed from the execution of the instructions, physical registers used by the instructions being de-allocated, etc.

The core 706 may also include a bus unit 714 to enable communication between components of the processor core 706 and other components (such as the components discussed with reference to FIG. 8) via one or more buses (e.g., buses 804 and/or 812). The core 706 may also include one or more registers 816 to store data accessed by various components of the core 706 (such as values related to power consumption state settings).

Furthermore, even though FIG. 7 illustrates the control unit 720 to be coupled to the core 706 via interconnect 812, in various examples the control unit 720 may be located elsewhere such as inside the core 706, coupled to the core via bus 704, etc.

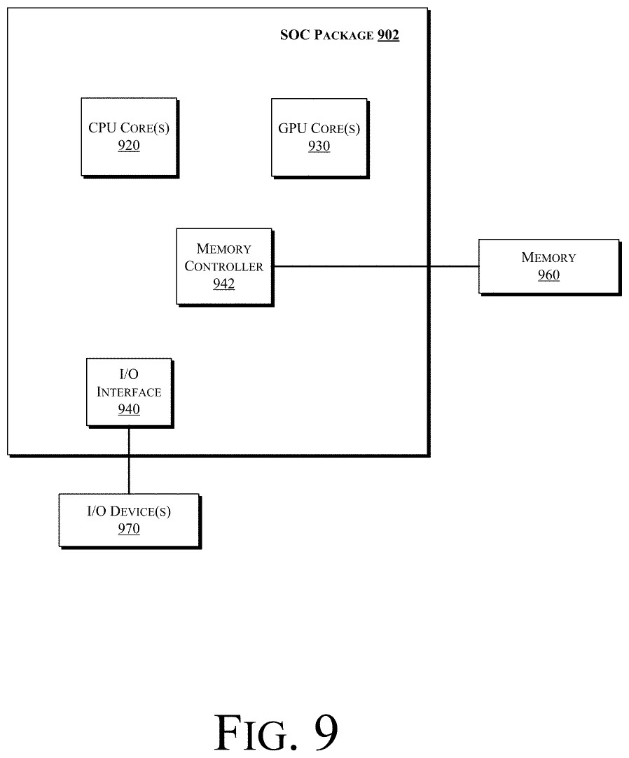

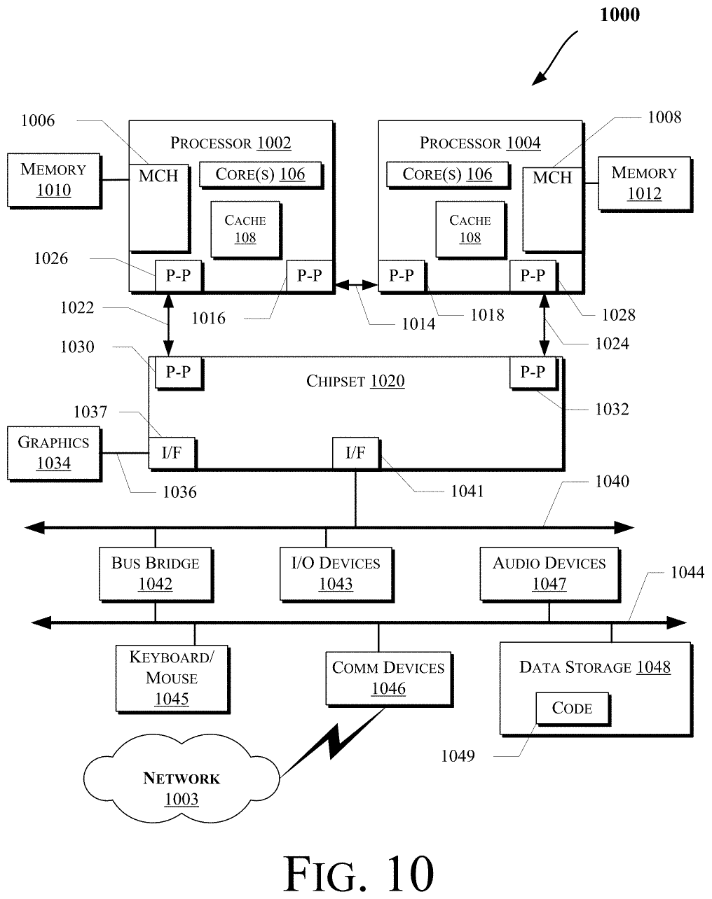

In some examples, one or more of the components discussed herein can be embodied as a System On Chip (SOC) device. FIG. 9 illustrates a block diagram of an SOC package in accordance with an example. As illustrated in FIG. 9, SOC 902 includes one or more processor cores 920, one or more graphics processor cores 930, an Input/Output (I/O) interface 940, and a memory controller 942. Various components of the SOC package 902 may be coupled to an interconnect or bus such as discussed herein with reference to the other figures. Also, the SOC package 902 may include more or less components, such as those discussed herein with reference to the other figures. Further, each component of the SOC package 902 may include one or more other components, e.g., as discussed with reference to the other figures herein. In one example, SOC package 902 (and its components) is provided on one or more Integrated Circuit (IC) die, e.g., which are packaged into a single semiconductor device.

As illustrated in FIG. 9, SOC package 902 is coupled to a memory 960 (which may be similar to or the same as memory discussed herein with reference to the other figures) via the memory controller 942. In an example, the memory 960 (or a portion of it) can be integrated on the SOC package 902.

The I/O interface 940 may be coupled to one or more I/O devices 970, e.g., via an interconnect and/or bus such as discussed herein with reference to other figures. I/O device(s) 970 may include one or more of a keyboard, a mouse, a touchpad, a display, an image/video capture device (such as a camera or camcorder/video recorder), a touch surface, a speaker, or the like.

FIG. 10 illustrates a computing system 1000 that is arranged in a point-to-point (PtP) configuration, according to an example. In particular, FIG. 10 shows a system where processors, memory, and input/output devices are interconnected by a number of point-to-point interfaces.

As illustrated in FIG. 10, the system 1000 may include several processors, of which only two, processors 1002 and 1004 are shown for clarity. The processors 1002 and 1004 may each include a local memory controller hub (MCH) 1006 and 1008 to enable communication with memories 1010 and 1012.

In an example, the processors 1002 and 1004 may exchange data via a point-to-point (PtP) interface 1014 using PtP interface circuits 1016 and 1018, respectively. Also, the processors 1002 and 1004 may each exchange data with a chipset 1020 via individual PtP interfaces 1022 and 1024 using point-to-point interface circuits 1026, 1028, 1030, and 1032. The chipset 1020 may further exchange data with a high-performance graphics circuit 1034 via a high-performance graphics interface 1036, e.g., using a PtP interface circuit 1037.

The chipset 1020 may communicate with a bus 1040 using a PtP interface circuit 1041. The bus 1040 may have one or more devices that communicate with it, such as a bus bridge 1042 and I/O devices 1043. Via a bus 1044, the bus bridge 1043 may communicate with other devices such as a keyboard/mouse 1045, communication devices 1046 (such as modems, network interface devices, or other communication devices that may communicate with the computer network 1003), audio I/O device, and/or a data storage device 1048. The data storage device 1048 (which may be a hard disk drive or a NAND flash based solid state drive) may store code 1049 that may be executed by the processors 1004.

The following pertains to further examples.

Example 1 is an electronic device, comprising a processor and a power monitoring module comprising logic, at least partially including hardware logic, to monitor a power supply, and generate an alert in response to an alert condition for the power supply, and a communication module to transmit the alert to a remote device.

In Example 2, the subject matter of Example 1 can optionally include an arrangement in which the power supply comprises a primary power source and a secondary power source and the alert condition is triggered in response to the secondary power source being activated for a predetermined period of time.

In Example 3, the subject matter of any one of Examples 1-2 can optionally include logic, at least partly including hardware logic, to initialize at least one power management parameter for the power supply, and initialize at least one network address associated with the remote device.

In Example 4, the subject matter of any one of Examples 1-3 can optionally include an optical sensor to detect an illumination level of one or more optical outputs on the power supply.

In Example 5, the subject matter of any one of Examples 1-4 can optionally include an arrangement in which the communication module comprises logic, at least partially including hardware logic, to receive a status inquiry from the remote device, and the power management module further comprises logic, at least partially including hardware logic, which, in response to the status inquiry, is to collect a data set comprising a plurality of samples of the illumination level of the one or more optical outputs on the power supply, determine an average illumination level of the one or more optical outputs on the power supply over a predetermined time period, and generate an alert when the average illumination level falls outside a predetermined range.

In Example 6, the subject matter of any one of Examples 1-5 can optionally include logic, at least partially including hardware logic, to transmit the alert to the remote device.

In Example 7, the subject matter of any one of Examples 1-6 can optionally include an arrangement in which the power management module further comprises logic, at least partially including hardware logic, to receive an input on a predetermined input device, collect a data set comprising a plurality of samples of the illumination level of the one or more optical outputs on the power supply, determine an average illumination level of the one or more optical outputs on the power supply over a predetermined time period, and generate an alert when the average illumination level falls outside a predetermined range.

In Example 8 the subject matter of any one of Examples 1-7 can optionally include logic, at least partially including hardware logic, to transmit the alert to the remote device.

In Example 9, the subject matter of any one of Examples 1-8 can optionally include an arrangement in which the communication module comprises logic, at least partially including hardware logic, to receive a reset command from the remote device and the power management module further comprises logic, at least partially including hardware logic, which, in response to the status inquiry, is to reset one or more data registers in a memory of the electronic device.

In Example 10, the subject matter of any one of Examples 1-9 can optionally include logic, at least partially including hardware logic, to receive an input on a predetermined input device, collect a data set comprising a plurality of samples of the illumination level of the one or more optical outputs on the power supply, determine an average illumination level of the one or more optical outputs on the power supply over a predetermined time period, and store the average illumination level in a data register in a memory of the electronic device.

Example 11 is a power monitoring module comprising logic, at least partly including hardware logic, to monitor a power supply and generate an alert in response to an alert condition for the power supply and forward the alert to a communication module to transmit the alert to a remote device.

In Example 12, the subject matter of Example 11 can optionally include an arrangement in which the power supply comprises a primary power source and a secondary power source and the alert condition is triggered in response to the secondary power source being activated for a predetermined period of time.

In Example 13, the subject matter of any one of Examples 11-12 can optionally include logic, at least partly including hardware logic, to initialize at least one power management parameter for the power supply, and initialize at least one network address associated with the remote device.

In Example 14, the subject matter of any one of Examples 11-13 can optionally include an input to detect an illumination level of one or more optical outputs on the power supply.

In Example 15, the subject matter of any one of Examples 11-14 can optionally include logic, at least partially including hardware logic, to receive a status inquiry from the remote device, and the power management module further comprises logic, at least partially including hardware logic, which, in response to the status inquiry, is to collect a data set comprising a plurality of samples of the illumination level of the one or more optical outputs on the power supply, determine an average illumination level of the one or more optical outputs on the power supply over a predetermined time period, and generate an alert when the average illumination level falls outside a predetermined range.

In Example 16, the subject matter of any one of Examples 11-15 can optionally include logic, at least partially including hardware logic, to transmit the alert to the remote device.

In Example 17, the subject matter of any one of Examples 11-16 can optionally include an arrangement in which the power management module further comprises logic, at least partially including hardware logic, to receive an input on a predetermined input device, collect a data set comprising a plurality of samples of the illumination level of the one or more optical outputs on the power supply, determine an average illumination level of the one or more optical outputs on the power supply over a predetermined time period, and generate an alert when the average illumination level falls outside a predetermined range.

In Example 18 the subject matter of any one of Examples 11-17 can optionally include logic, at least partially including hardware logic, to transmit the alert to the remote device.

In Example 19, the subject matter of any one of Examples 11-18 can optionally logic, at least partially including hardware logic, to receive a reset command from the remote device and the power management module further comprises logic, at least partially including hardware logic, which, in response to the status inquiry, is to reset one or more data registers in a memory of the electronic device.

In Example 20, the subject matter of any one of Examples 11-19 can optionally include logic, at least partially including hardware logic, to receive an input on a predetermined input device, collect a data set comprising a plurality of samples of the illumination level of the one or more optical outputs on the power supply, determine an average illumination level of the one or more optical outputs on the power supply over a predetermined time period, and store the average illumination level in a data register in a memory of the electronic device.

Example 21 is a computer program product comprising logic instructions stored on a non-transitory computer readable medium which, when executed by a processor, configure the processor to monitor a power supply, and generate an alert in response to an alert condition for the power supply and forward the alert to a communication module to transmit the alert to a remote device.

In Example 22, the subject matter of Example 21 can optionally include an arrangement in which the power supply comprises a primary power source and a secondary power source and the alert condition is triggered in response to the secondary power source being activated for a predetermined period of time.

In Example 23, the subject matter of any one of Examples 21-22 can optionally include logic instructions which, when executed, configure the processor to initialize at least one power management parameter for the power supply, and initialize at least one network address associated with the remote device.

In Example 14, the subject matter of any one of Examples 21-23 can optionally include logic instructions which, when executed, configure the processor to implement an interface to detect an illumination level of one or more optical outputs on the power supply.

In Example 25, the subject matter of any one of Examples 21-24 can optionally include logic instructions which, when executed, configure the processor to receive a status inquiry from the remote device, and the power management module further comprises logic, at least partially including hardware logic, which, in response to the status inquiry, is to collect a data set comprising a plurality of samples of the illumination level of the one or more optical outputs on the power supply, determine an average illumination level of the one or more optical outputs on the power supply over a predetermined time period, and generate an alert when the average illumination level falls outside a predetermined range.

The terms “logic instructions” as referred to herein relates to expressions which may be understood by one or more machines for performing one or more logical operations. For example, logic instructions may comprise instructions which are interpretable by a processor compiler for executing one or more operations on one or more data objects. However, this is merely an example of machine-readable instructions and examples are not limited in this respect.

The terms “computer readable medium” as referred to herein relates to media capable of maintaining expressions which are perceivable by one or more machines. For example, a computer readable medium may comprise one or more storage devices for storing computer readable instructions or data. Such storage devices may comprise storage media such as, for example, optical, magnetic or semiconductor storage media. However, this is merely an example of a computer readable medium and examples are not limited in this respect.

The term “logic” as referred to herein relates to structure for performing one or more logical operations. For example, logic may comprise circuitry which provides one or more output signals based upon one or more input signals. Such circuitry may comprise a finite state machine which receives a digital input and provides a digital output, or circuitry which provides one or more analog output signals in response to one or more analog input signals. Such circuitry may be provided in an application specific integrated circuit (ASIC) or field programmable gate array (FPGA). Also, logic may comprise machine-readable instructions stored in a memory in combination with processing circuitry to execute such machine-readable instructions. However, these are merely examples of structures which may provide logic and examples are not limited in this respect.

Some of the methods described herein may be embodied as logic instructions on a computer-readable medium. When executed on a processor, the logic instructions cause a processor to be programmed as a special-purpose machine that implements the described methods. The processor, when configured by the logic instructions to execute the methods described herein, constitutes structure for performing the described methods. Alternatively, the methods described herein may be reduced to logic on, e.g., a field programmable gate array (FPGA), an application specific integrated circuit (ASIC) or the like.

In the description and claims, the terms coupled and connected, along with their derivatives, may be used. In particular examples, connected may be used to indicate that two or more elements are in direct physical or electrical contact with each other. Coupled may mean that two or more elements are in direct physical or electrical contact. However, coupled may also mean that two or more elements may not be in direct contact with each other, but yet may still cooperate or interact with each other.

Reference in the specification to “one example” or “some examples” means that a particular feature, structure, or characteristic described in connection with the example is included in at least an implementation. The appearances of the phrase “in one example” in various places in the specification may or may not be all referring to the same example.

Although examples have been described in language specific to structural features and/or methodological acts, it is to be understood that claimed subject matter may not be limited to the specific features or acts described. Rather, the specific features and acts are disclosed as sample forms of implementing the claimed subject matter.

1-25. (canceled)

26. An electronic device, comprising:
a processor; and
a power monitoring module comprising logic, at least partially including hardware logic, to:
monitor a power supply; and
generate an alert in response to an alert condition for the power supply; and
a communication module to transmit the alert to a remote device.

27. The electronic device of claim 26, wherein:
the power supply comprises a primary power source and a secondary power source; and
the alert condition is triggered in response to the secondary power source being activated for a predetermined period of time.

28. The electronic device of claim 26, wherein the power monitoring module comprises logic, at least partially including hardware logic, to:
initialize at least one power management parameter for the power supply; and
initialize at least one network address associated with the remote device.

29. The electronic device of claim 26, further comprising an optical sensor to detect an illumination level of one or more optical outputs on the power supply.

30. The electronic device of claim 29, wherein:
the communication module comprises logic, at least partially including hardware logic, to receive a status inquiry from the remote device; and
the power management module further comprises logic, at least partially including hardware logic, which, in response to the status inquiry, is to:
collect a data set comprising a plurality of samples of the illumination level of the one or more optical outputs on the power supply;
determine an average illumination level of the one or more optical outputs on the power supply over a predetermined time period; and
generate an alert when the average illumination level falls outside a predetermined range.

31. The electronic device of claim 30, wherein the communication module comprises logic, at least partially including hardware logic, to:
transmit the alert to the remote device.

32. The electronic device of claim 29, wherein the power management module further comprises logic, at least partially including hardware logic, to:
receive an input on a predetermined input device;
collect a data set comprising a plurality of samples of the illumination level of the one or more optical outputs on the power supply;
determine an average illumination level of the one or more optical outputs on the power supply over a predetermined time period; and
generate an alert when the average illumination level falls outside a predetermined range.

33. The electronic device of claim 32, wherein the communication module comprises logic, at least partially including hardware logic, to:
transmit the alert to the remote device.

34. The electronic device of claim 26, wherein:
the communication module comprises logic, at least partially including hardware logic, to receive a reset command from the remote device; and
the power management module further comprises logic, at least partially including hardware logic, which, in response to the status inquiry, is to reset one or more data registers in a memory of the electronic device.

35. The electronic device of claim 29, wherein the power management module further comprises logic, at least partially including hardware logic, to:
receive an input on a predetermined input device;
collect a data set comprising a plurality of samples of the illumination level of the one or more optical outputs on the power supply;
determine an average illumination level of the one or more optical outputs on the power supply over a predetermined time period; and
store the average illumination level in a data register in a memory of the electronic device.

36. A power monitoring module comprising logic, at least partly including hardware logic, to:
monitor a power supply; and
generate an alert in response to an alert condition for the power supply; and
forward the alert to a communication module to transmit the alert to a remote device.

37. The power monitoring module of claim 36, wherein:
the power supply comprises a primary power source and a secondary power source; and
the alert condition is triggered in response to the secondary power source being activated for a predetermined period of time.

38. The power monitoring module of claim 36, further comprising logic, at least partially including hardware logic, to:
initialize at least one power management parameter for the power supply; and
initialize at least one network address associated with the remote device.

39. The power monitoring module of claim 36, further comprising an input to receive an illumination level of one or more optical outputs on the power supply.

40. The power monitoring module of claim 39, further comprising logic to:
receive a status inquiry from the remote device; and
collect a data set comprising a plurality of samples of the illumination level of the one or more optical outputs on the power supply;
determine an average illumination level of the one or more optical outputs on the power supply over a predetermined time period; and
generate an alert when the average illumination level falls outside a predetermined range.

41. The power monitoring module of claim 40, further comprising logic, at least partially including hardware logic, to:
transmit the alert to the remote device.

42. The power monitoring module of claim 39, further comprising logic, at least partially including hardware logic, to:
receive an input on a predetermined input device;
collect a data set comprising a plurality of samples of the illumination level of the one or more optical outputs on the power supply;
determine an average illumination level of the one or more optical outputs on the power supply over a predetermined time period; and
generate an alert when the average illumination level falls outside a predetermined range.

43. The power monitoring module of claim 42, further comprising logic, at least partially including hardware logic, to:
transmit the alert to the remote device.

44. The power monitoring module of claim 36, further comprising logic, at least partially including hardware logic, to:
receive a reset command from the remote device; and
reset one or more data registers in a memory communicatively coupled to the power monitoring module.

45. The power monitoring module of claim 39, further comprising logic, at least partially including hardware logic, to:
receive an input on a predetermined input device;
collect a data set comprising a plurality of samples of the illumination level of the one or more optical outputs on the power supply;
determine an average illumination level of the one or more optical outputs on the power supply over a predetermined time period; and
store the average illumination level in a data register in a memory of the electronic device.

46. A computer program product comprising logic instructions stored on a non-transitory computer readable medium which, when executed by a processor, configure the processor to:
monitor a power supply; and
generate an alert in response to an alert condition for the power supply; and
forward the alert to a communication module to transmit the alert to a remote device.

47. The computer program product of claim 46, wherein:
the power supply comprises a primary power source and a secondary power source; and
the alert condition is triggered in response to the secondary power source being activated for a predetermined period of time.

48. The computer program product of claim 46, further comprising logic instructions which, when executed, configure the processor to:
initialize at least one power management parameter for the power supply; and
initialize at least one network address associated with the remote device.

49. The computer program product of claim 46, further comprising logic instructions which, when executed, configure the processor to implement an interface to receive an illumination level of one or more optical outputs on the power supply.

50. The computer program product of claim 49, further comprising logic instructions which, when executed, configure the processor to:
receive a status inquiry from the remote device; and
collect a data set comprising a plurality of samples of the illumination level of the one or more optical outputs on the power supply;
determine an average illumination level of the one or more optical outputs on the power supply over a predetermined time period; and
generate an alert when the average illumination level falls outside a predetermined range.
